(19) United States
(12) Patent Application Publication
(10) Pub. No.: US 2026/0096302 A1
(43) Pub. Date: Apr. 2, 2026

(54) DISPLAY PANEL AND DISPLAY DEVICE

(71) Applicant: HKC CORPORATION LIMITED, SHENZHEN (CN)

(72) Inventors: Wenyu YI, SHENZHEN (CN); Lidan YE, SHENZHEN (CN)

(73) Assignee: HKC CORPORATION LIMITED, SHENZHEN (CN)

(21) Appl. No.: 19/321,238

(22) Filed: Sep. 7, 2025

(30) Foreign Application Priority Data
Sep. 30, 2024 (CN) 202411393307.2

(51) Int. Cl. H10K 59/123; H10K 59/35; H10K 59/80

(52) U.S. Cl. CPC H10K 59/123; H10K 59/353; H10K 59/80515

(57) ABSTRACT

The present application provides a display panel and a display device. The display panel includes a silicon-based driving substrate and a light-emitting carrier plate. The light-emitting carrier plate is bonded to the silicon-based driving substrate. The light-emitting carrier plate includes a glass substrate and a plurality of sub-pixels of different colors. The glass substrate has a plurality of anode conductive vias. Each of the sub-pixels includes an anode. A surface of a side of the anode of each of the sub-pixels close to the glass substrate is defined as a connecting surface. The connecting surface covers and contacts a corresponding one of the anode conductive vias, and a contact region is formed on the connecting surface. The sub-pixels of different colors have different service lives. The sub-pixel having shorter service life has a larger contact region on the anode.

### CROSS REFERENCE TO RELATED APPLICATIONS

The present disclosure claims priority to Chinese Patent Application No. 202411393307.2, filed on September 30, 2024, the contents of which are herein incorporated by reference in their entirety.

### TECHNICAL FIELD

The present disclosure relates to but not limited to a field of display technologies, and in particular to a display panel and a display device.

### BACKGROUND

Organic light-emitting diode (OLED), also known as organic electroluminescence display (OELD), is widely used, since its display technology has features such as high contrast, wide viewing angle, and bendability, which cannot be achieved by liquid crystal display technology. Further, since the OLED has characteristics such as being thin, light, power-saving and the like, it represents a direction of display technology.

The OELD includes red pixels, green pixels, and blue pixels. The service life of blue pixels is relatively lower than that of the red pixels and the green pixels. During long-term use, the luminous brightness of the blue pixels may decrease, resulting in insufficient intensity of blue light, and thus affecting the service life and display effect of a display panel.

### SUMMARY

The present disclosure provides a display panel, and the display panel includes a silicon-based driving substrate and a light-emitting carrier plate. The light-emitting carrier plate is bonded to the silicon-based driving substrate. The light-emitting carrier plate includes a glass substrate and a plurality of sub-pixels of different colors. The glass substrate has a plurality of anode conductive vias. The plurality of sub-pixels of different colors are disposed on a surface of a side of the glass substrate. Each of the sub-pixels includes an anode, and the anode of each of the sub-pixels is arranged in one-to-one correspondence with one of the plurality of anode conductive vias. A surface of a side of the anode of each of the sub-pixels close to the glass substrate is defined as a connecting surface. The connecting surface covers and contacts a corresponding one of the anode conductive vias, and a contact region is formed on the connecting surface. The sub-pixels of different colors have different service lives. The sub-pixel having shorter service life has a larger contact region on the anode.

The present disclosure further provides a display device, the display device includes a mainboard and a display panel, and the display panel includes a silicon-based driving substrate and a light-emitting carrier plate. The light-emitting carrier plate is bonded to the silicon-based driving substrate. The light-emitting carrier plate includes a glass substrate and a plurality of sub-pixels of different colors. The glass substrate has a plurality of anode conductive vias. The plurality of sub-pixels of different colors are disposed on a surface of a side of the glass substrate. Each of the sub-pixels includes an anode, and the anode of each of the sub-pixels is arranged in one-to-one correspondence with one of the plurality of anode conductive vias. A surface of a side of the anode of each of the sub-pixels close to the glass substrate is defined as a connecting surface. The connecting surface covers and contacts a corresponding one of the anode conductive vias, and a contact region is formed on the connecting surface. The sub-pixels of different colors have different service lives. The sub-pixel having shorter service life has a larger contact region on the anode.

### BRIEF DESCRIPTION OF THE DRAWINGS

In order to more clearly illustrate the technical solutions in the embodiments of the present disclosure, the following briefly describes the accompanying drawings used in the embodiments. It is apparent that the drawings in the following description are only some embodiments of the present disclosure. For persons of ordinary skill in the art, other drawings may be derived from these drawings without creative effort.

FIG. 1 is a structural schematic view of sub-pixels and anode conductive vias provided by the related art.

FIG. 2 is a structural schematic view of a longitudinal section of a display panel provided by an embodiment of the present disclosure.

FIG. 3 is a structural schematic view of sub-pixels and anode conductive vias provided by an embodiment of the present disclosure.

FIG. 4 is a partial enlargement structure schematic view of the P region in FIG. 3.

FIG. 5 is a structural schematic view of a display device provided by an embodiment of the present disclosure.

### DETAILED DESCRIPTION

The technical solutions in the embodiments of the present disclosure will be described in detail below with reference to the accompanying drawings.

In the following description, specific details such as system architectures, interfaces, and techniques are provided for illustrative purposes only, not to limit the scope of the disclosure.

In order to make the purpose, technical solutions and advantages of the present disclosure clearer, the following will be described in further detail in conjunction with drawings. Obviously, the described embodiments are only a part of embodiments of the present disclosure, not all embodiments. Based on the embodiments in the present disclosure, all other embodiments obtained by those skilled in the art without creative labor are within the scope of protection of the present disclosure.

In the following description, terms “first/second/third” are used only to distinguish similar objects and do not represent a specific order for the objects, and it is understood that the terms “first/second/third” may be interchanged in a specific order or sequence so that the embodiments of the present disclosure described can be implemented in an order other than the order or sequence described in the drawings and specification. The terms “first”, “second” and “third” in this disclosure are used for descriptive purposes only and are not to be construed as indicating or implying relative importance or as implicitly indicating the quantity of the technical features indicated. Thus, a feature defined as “first”, “second”, or “third” may explicitly or implicitly include at least one of the features. In the description of this disclosure, “multiple” means at least two, such as two, three, etc., unless otherwise expressly specified. All directional indications in the embodiments of this disclosure (e.g. up, down, left, right, front, back...) are only used to explain the relative position relationship and motion between the components in a specific attitude (as shown in the drawings). When the specific attitude changes, the directional indication may also change accordingly. Furthermore, the terms “including” and “having”, and any variation thereof, are intended to cover non-exclusive inclusion. For example, a process, method, system, product or device including a series of steps or units is not limited to the listed steps or units, but optionally also includes steps or units not listed, or optionally includes other steps or units inherent to those processes, methods, products or devices.

A term “embodiment” in the following description describes a subset of all possible embodiments, but it is understood that “embodiment” may be the same subset or a different subset of all possible embodiments, and may be combined with each other without conflict.

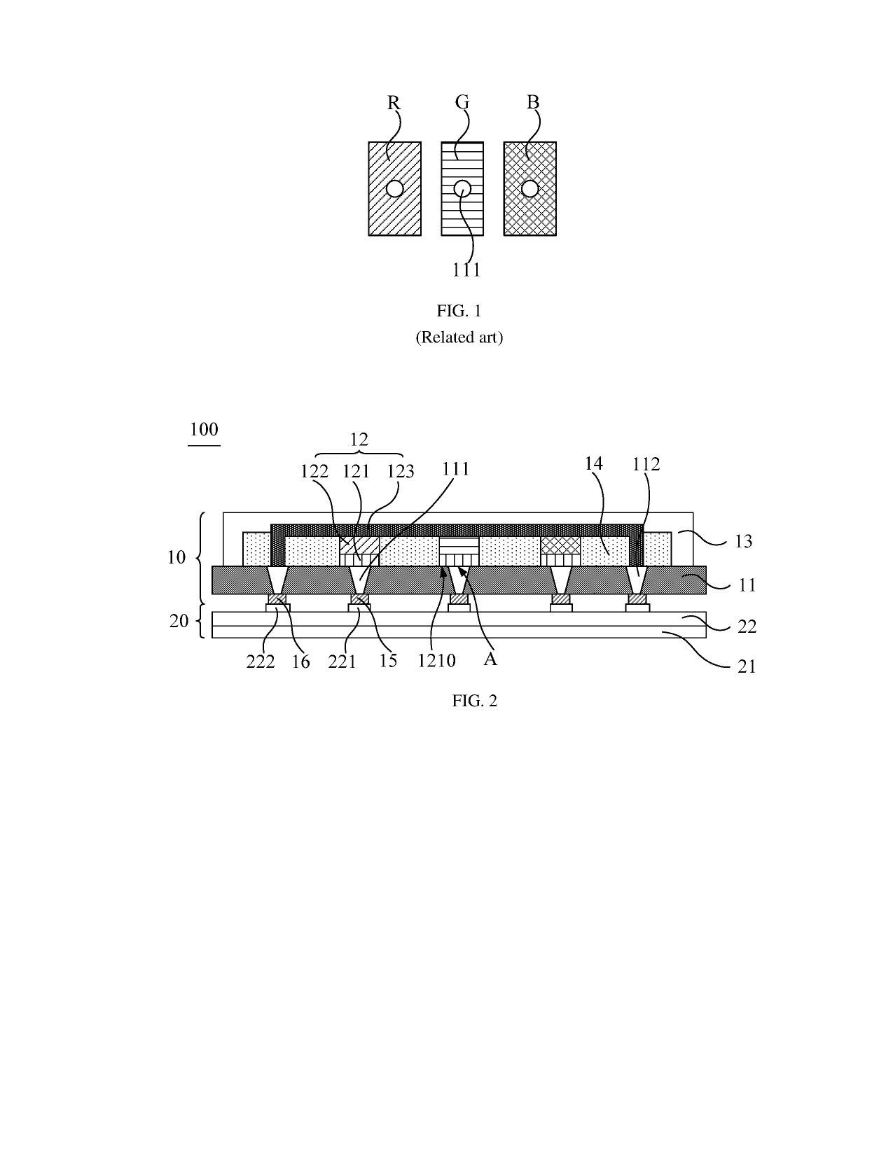

Please refer to FIG. 1. FIG. 1 is a structural schematic view of sub-pixels and anode conductive vias provided by the related art.

In the related art, due to different service lives of red pixels R, blue pixels B, and green pixels G, during long-term use, the luminous brightness of the blue pixels B with a short service life may decrease, a color cast problem is likely to occur, and a service life of a display panel (not shown in FIG. 1) is affected. Secondly, anode conductive vias 111 in the related art are usually circular holes, and the size of the anode conductive via 111 corresponding to each of sub-pixels is generally the same, so that the current density of an anode (not shown in FIG. 1) of each of the sub-pixels is the same. Generally, the service life of each of the blue pixels B may be improved by increasing a light-emitting area of each of the blue pixels B, thereby improving the service life of the display panel.

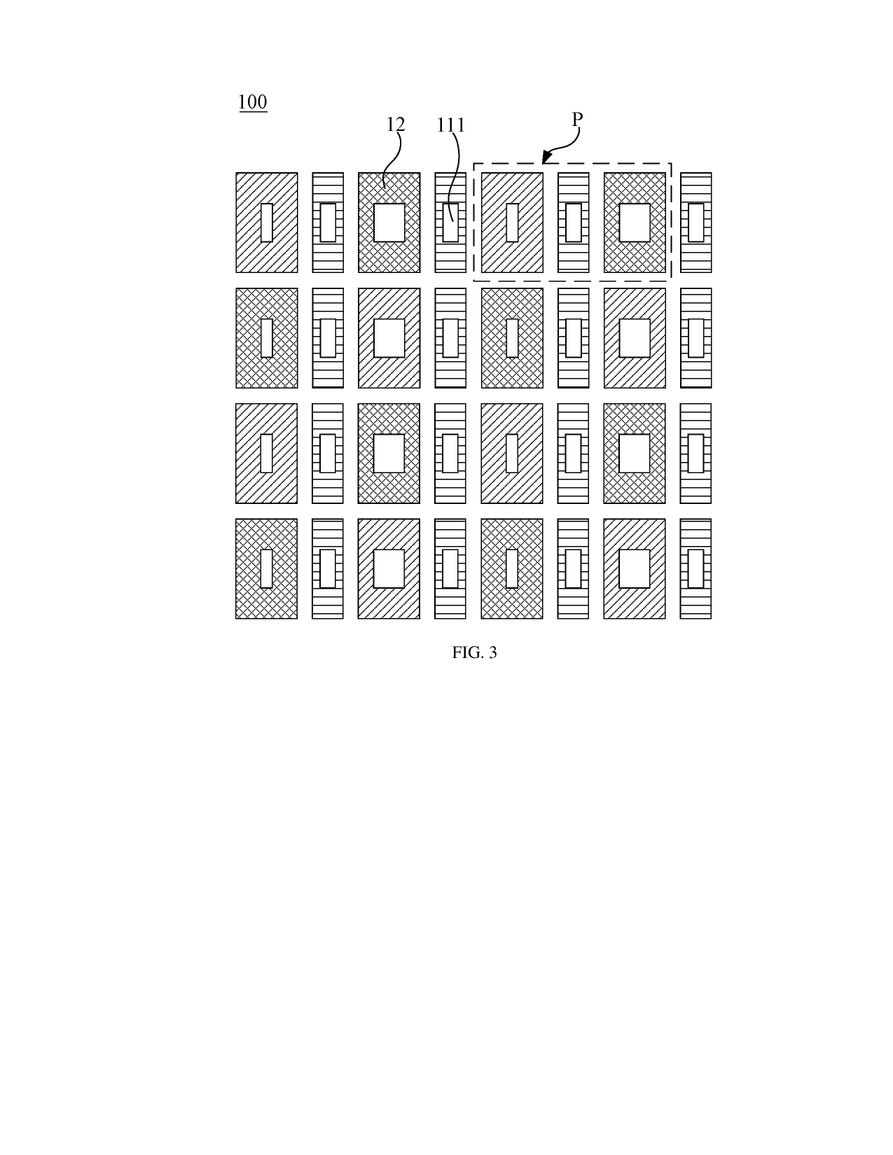

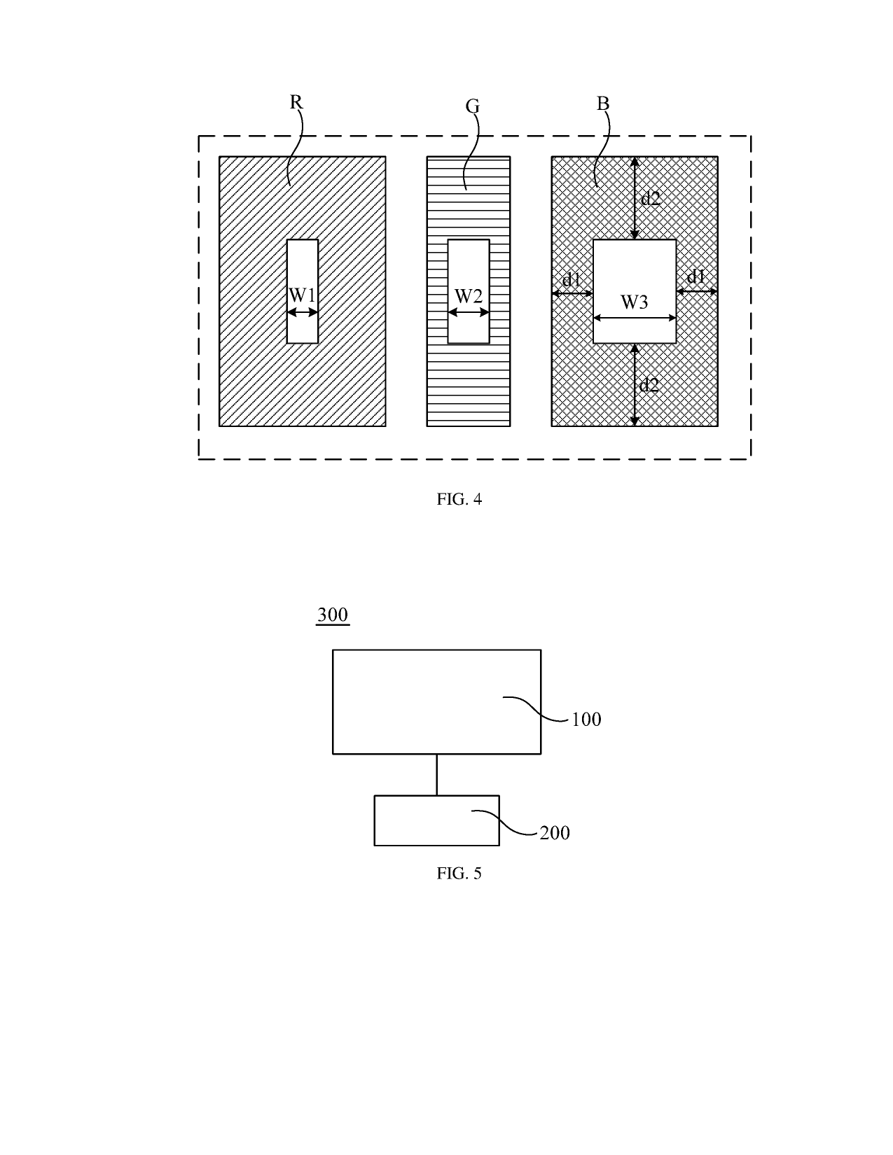

Please refer to FIG. 2 to FIG. 4. FIG. 2 is a structural schematic view of a longitudinal section of a display panel provided by an embodiment of the present disclosure. FIG. 3 is a structural schematic view of sub-pixels and anode conductive vias provided by an embodiment of the present disclosure. FIG. 4 is a partial enlargement structure schematic view of the P region in FIG. 3.

In order to improve service life of a display panel 100, a display panel 100 is provided by the present disclosure. The display panel 100 includes a silicon-based driving substrate 20 and a light-emitting carrier plate 10. The light-emitting carrier plate 10 is bonded to the silicon-based driving substrate 20. The light-emitting carrier plate 10 includes a glass substrate 11 and a plurality of sub-pixels 12 of different colors. The glass substrate 11 has a plurality of anode conductive vias 111. The plurality of sub-pixels 12 of different colors are disposed on a surface of a side of the glass substrate 11. Each of the sub-pixels 12 includes an anode 121, and the anode 121 of each of the sub-pixels 12 is arranged in one-to-one correspondence with one of the anode conductive vias 111. A surface of a side of the anode 121 of each of the sub-pixels 12 close to the glass substrate 11 is defined as a connecting surface 1210. The connecting surface 1210 covers and contacts a corresponding one of the anode conductive vias 111, and a contact region A is formed on the connecting surface 1210. The sub-pixels 12 of different colors have different service lives. The sub-pixel 12 having a shorter service life has a larger contact region A on the anode 121.

By increasing the area of the contact region A of the anode 121 in each of the sub-pixels 12 with the short service life, the current density on the anode 121 of each of the sub-pixels 12 with the short service life is reduced, thereby increasing the service life of each of the sub-pixels 12 with the certain color and improving the service life of the display panel 100. Secondly, by separately fabricating the light-emitting carrier plate 10 with the sub-pixels 12 and the silicon-based driving substrate 20, and bonding the light-emitting carrier plate 10 with the silicon-based driving substrate 20, the sub-pixels 12 are not directly fabricated on the silicon-based driving substrate 20. This reduces the impact of a sub-pixel evaporation process on a driving circuit of the silicon-based driving substrate 20, thereby minimizing losses caused by subsequent process errors and lowering the manufacturing cost of the silicon-based driving substrate 20.

The silicon-based driving substrate 20 may include a silicon substrate 21 and a driving circuit layer 22. The driving circuit layer 22 may be arranged on the side of the silicon substrate 21 close to the light-emitting carrier plate 10.

The silicon substrate 21 refers to a substrate based on a single-crystalline silicon material.

The driving circuit layer 22 includes an active driving circuit (not shown) integrated on the silicon substrate 21 using the complementary metal-oxide semiconductor (CMOS) process.

The silicon-based driving substrate 20 and the light-emitting carrier plate 10 are fabricated separately, which may improve production efficiency. Secondly, separate fabrication may further avoid the impact of the evaporation process on the silicon-based driving substrate 20 and reduce the loss of the silicon-based driving substrate 20. That is to say, from the perspective of process, fabricating the silicon-based driving substrate 20 and the light-emitting carrier plate 10 separately may not only improve the yield rate but also reduce costs.

The glass substrate 11 may further have a plurality of cathode conductive holes 112, the cathode conductive holes 112 and the anode conductive vias 111 are arranged at intervals.

The anode conductive vias 111 may penetrate the glass substrate 11 in a direction perpendicular to the glass substrate 11, and the cathode conductive holes 112 may penetrate the glass substrate 11 in the direction perpendicular to the glass substrate 11.

Specifically, each of the anode conductive vias 111 may include a via and conductive materials filled in the via, and each of the cathode conductive holes 112 may include a via and conductive materials filled in the via. The conductive materials in the anode conductive vias 111 and the cathode conductive holes 112 are not limited and may be selected according to actual needs. The vias may penetrate the glass substrate 11 in the direction perpendicular to the glass substrate 11. The via of each of the cathode conductive holes 112 and each of the anode conductive vias 111 may be fabricated by the through-glass via (TGV) technology.

It should be understood that, compared with the through-silicon-via technology, the TGV technology has the advantages of excellent high-frequency electrical characteristics, low cost, simple process, and strong mechanical stability.

Compared with the related art in which the sub-pixels 12 are fabricated on the silicon-based driving substrate 20 and are electrically connected with the silicon-based driving substrate 20 through the through-silicon vias, the sub-pixels 12 in the present disclosure are disposed on the glass substrate 11 and are bonded to the silicon-based driving substrate 20 through the through-glass-vias, costs may be reduced and high-frequency electrical characteristics may be improved.

The sub-pixels 12 may be arranged on a surface of a side of the glass substrate 11 away from the silicon-based driving substrate 20. Each of the sub-pixels 12 may be arranged corresponding to one of the anode conductive vias 111. An orthographic projection of each of the sub-pixels 12 on the glass substrate 11 may cover the corresponding one of the anode conductive vias 111, so as to prevent the anode conductive vias 111 from occupying the space between the sub-pixels 12, which is beneficial to improving the aperture ratio of the sub-pixels 12.

Each of the sub-pixels 12 may be an OLED and may include an anode 121, a light-emitting layer 122 and a cathode 123 sequentially stacked.

The anode 121 of each of the sub-pixels 12 may be electrically connected to the silicon-based driving substrate 20 through the corresponding one of the anode conductive vias 111. The cathode 123 of each of the sub-pixels 12 may be electrically connected with the silicon-based driving substrate 20 through the cathode conductive holes 112.

The connecting surface 1210 of the anode 121 of each sub-pixel 12 may also be a surface of a side where the anode 121 of each sub-pixel 12 contacts the corresponding one of the anode conductive vias 111. The region of the connecting surface 1210 that contacts the corresponding one of the anode conductive vias 111 may be defined as the contact region A. That is, the contact region A may be a part of the anode 121 contact an end surface of the corresponding one of the anode conductive vias 111 close to a corresponding one of the sub-pixels 12. The anode 121 of each sub-pixel 12 covers the corresponding one of the anode conductive vias 111, so that the size of the contact region A is equal to the size of the end surface of the corresponding anode conductive via 111 close to the corresponding sub-pixel 12.

It should be understood that, in ideal conditions, the shape and size of the contact region A are the same as those of an end of the via in the corresponding one of the anode conductive vias 111 facing the corresponding sub-pixel 12. While in practical situations, the conductive material may overflow from the via, causing the contact region A to be slightly larger than the end of the via in the corresponding one of the anode conductive vias 111 facing the corresponding sub-pixel 12.

In some embodiments, the size of each of the sub-pixels 12 may be 6 microns to 15 microns. It should be understood that the size of the sub-pixels 12 may also be other values.

In some embodiments, the plurality of sub-pixels 12 of different colors may be respectively defined as red pixels R, green pixels G, and blue pixels B. The service life of the red pixels R may be greater than that of the green pixels G, and the service life of the green pixels G may be greater than that of the blue pixels B. The area of the contact region A of each of the red pixels R may be smaller than that of the contact region A of each of the green pixels G. The area of the contact region A of each of the green pixels G may be smaller than that of the contact region A of each of the blue pixels B. By increasing the area of the contact region A of each of the blue pixels B, a pick-up current of the anode 121 of each of the blue pixels B may be reduced, so as to improve the service life of the blue pixels B and further improve the service life of the display panel 100.

In other embodiments, the sub-pixels 12 may include sub-pixels 12 of two or more colors. The sub-pixel 12 may also be of other colors, which can be selected according to actual needs.

In some embodiments, the ratio of the light-emitting area of the red pixels R, the light-emitting area of the green pixels G, and the light-emitting area of the blue pixels B may be 2:1:2, which may be beneficial for subsequent light mixing tuning. Compared with the related art, in which the service life of the blue pixels B is improved only by increasing the light-emitting area of the blue pixels B, the embodiments of the present disclosure further increase the area of the contact region A of each of the blue pixels B on the basis of the related art, which may further improve the service life of the blue pixels B.

It should be understood that in other embodiments, the ratio of the light-emitting area of the red pixels R, the light-emitting area of the green pixels G, and the light-emitting area of the blue pixels B may be other values, which may be selected according to actual needs.

In some embodiments, the contact region A of each sub-pixel 12 may be located at a geometric center of a corresponding connecting surface 1210. In other words, in the direction parallel to the glass substrate 11, each of the anode conductive vias 111 may be located at the geometric center of the corresponding one of the sub-pixels 12, which may ensure that the current is more evenly distributed throughout the anode 121 of each sub-pixel 12, and which may be beneficial for reducing heat generation and improving the service life of the sub-pixels 12.

It should be understood that in other embodiments, the contact region A may be located at other positions on the corresponding connecting surface 1210, as long as it is ensured that the anode 121 of each of the sub-pixels 12 covers the end surface of the corresponding anode conductive via 111 close to the corresponding sub-pixel 12.

In some embodiments, in the direction parallel to the glass substrate 11, the shape of the contact region A may be the same as or similar to that of the corresponding sub-pixel 12. That is, the shape of the contact region A may be the same as or similar to that of the corresponding connecting surface 1210.

It should be understood that configuring the shape of the contact region A to be the same as or similar to that of the corresponding sub-pixel 12 may help to improve the uniformity of current distribution, reduce local overheating, and thus improve the reliability and service life of the sub-pixels 12.

In other embodiments, in the direction parallel to the glass substrate 11, the shape of the contact region A may be different from that of the corresponding sub-pixel 12, and the selection can be made according to actual needs.

In some embodiments, the shapes of the contact regions A of all sub-pixels 12 may be the same, which facilitates the fabrication of the anode conductive vias 111.

In other embodiments, the shapes of the contact regions A of sub-pixels 12 of different colors may also be different, and the selection can be made according to actual needs.

It should be understood that the shape and size of the contact region A of each of the sub-pixels in the embodiments of the present disclosure may depend on the shape and size of the end of the via in the corresponding anode conductive via 111 facing the corresponding sub-pixel 12.

In some embodiments, an area of the contact region A may account for 1/4 to 1/2 of an area of the corresponding connecting surface 1210. Thus, without affecting the pixel aperture of the sub-pixels 12, the yield of the anode conductive vias 111 and the electrical conductivity between the anode 121 of each of the sub-pixels 12 and the corresponding anode conductive via 111 are ensured.

In some embodiments, in the direction parallel to the glass substrate 11, the shapes of the sub-pixels 12 and the contact region A may be both rectangular. The sub-pixels 12 may be arranged in an array. In each row of the sub-pixels 12, the sub-pixels 12 of different colors may be arranged side by side periodically and be aligned. In each row of the sub-pixels 12, the contact regions A of the sub-pixels 12 of different colors may respectively form a plurality of rectangles with equal lengths and unequal widths, and the short sides of the rectangles of the contact regions A may be aligned. The short sides of the rectangles of the contact regions A may be parallel to a row direction of the sub-pixels 12.

Specifically, in this embodiment, in odd-numbered rows of the sub-pixels 12, the red pixels R, the green pixels G, the blue pixels B, and the green pixels G may be arranged side by side in sequence, and be periodically arranged in the row direction of the sub-pixels 12 in this sorting manner. In even-numbered rows of the sub-pixels 12, the blue pixels B, the green pixels G, the red pixels R, and the green pixels G may be arranged side by side in sequence, and be periodically arranged in the row direction of the sub-pixels 12 in this sorting manner. In odd-numbered columns of the sub-pixels 12, the red pixels R and the blue pixels B may be arranged alternately in sequence. In even-numbered columns of the sub-pixels 12, the green pixels G may be arranged in sequence. The long side of the rectangle formed by the sub-pixels 12 may be parallel to a column direction of the sub-pixels 12. In each column of the sub-pixels 12, the long sides of the rectangles formed by the sub-pixels 12 may be aligned. This arrangement of the sub-pixels 12 provided in this embodiment may be beneficial for improving the color cast phenomenon.

In other embodiments, the sub-pixels 12 may also be arranged in other ways, and the arrangement can be selected according to actual needs.

In each row of the sub-pixels 12, the short sides of the rectangles formed by the sub-pixels 12 may be aligned in the row direction of the sub-pixels 12. It can be understood that the sub-pixels 12 of different colors respectively form the plurality of rectangles with equal lengths but unequal widths. In each row of the sub-pixels 12, in the direction parallel to the glass substrate 11, the centers of the rectangles formed by the sub-pixels 12 may be located on a same straight-line row.

It should be noted that the rectangles formed by the sub-pixels 12 in the present disclosure may be understood as follows: in the direction parallel to the glass substrate 11, the shapes of the sub-pixels 12 are rectangular; it may also be understood that orthographic projections of the sub-pixels 12 on the glass substrate 11 are rectangles.

In each row of the sub-pixels 12, the contact regions A of the sub-pixels 12 of different colors may respectively form the plurality of rectangles with equal lengths but unequal widths, and the short sides of the rectangles formed by the sub-pixels 12 may be aligned. It can be understood that in each row of the sub-pixels 12, the centers of the rectangles formed by the contact regions A of the sub-pixels 12 may be on a same straight line. This arrangement helps to simplify the fabrication of the anode conductive vias 111.

In this embodiment, a width W1 of the contact region A of each of the red pixels R may be less than a width W2 of the contact region A of each of the green pixels G. The width W2 of the contact region A of each of the green pixels G may be less than a width W3 of the contact region A of each of the blue pixels B.

In some embodiments, in each of the sub-pixels 12, the short side of the rectangle formed by the contact region A may be parallel to the short side of the rectangle formed by the corresponding one of the sub-pixels 12. This arrangement helps to uniformly adjust the distance between the sides where the contact region A and the connecting surface 1210 of the anode 121 of the corresponding sub-pixel 12 are close to each other, avoiding the situation where the distance between the sides where the contact region A and the connecting surface 1210 of the anode 121 of the corresponding sub-pixel 12 is close to each other are extremely small, which affects the uniform distribution of the current.

In this embodiment, in the row direction of the sub-pixels 12, the distances between the sides of the contact region A and the connecting surface 1210 of the corresponding anode 121 that are close to each other in a single one of the sub-pixels 12 are all equal. That is, in a single one of the sub-pixels 12, the distance between a left side of the contact region A and a left side of the connecting surface 1210 of the corresponding anode 121 may be equal to the distance between a right side of the contact region A and a right side of the connecting surface 1210 of the corresponding anode 121.

In the column direction of the sub-pixels 12, the distances between the sides of the contact region A and the connecting surface 1210 of the corresponding anode 121 that are close to each other in a single one of the sub-pixels 12 may all be equal. That is, in a single one of the sub-pixels 12, the distance between an upper side of the contact region A and an upper side of the connecting surface 1210 of the corresponding anode 121 may be equal to the distance between a lower side of the contact region A and a lower side of the connecting surface 1210 of the corresponding anode 121. This arrangement may be beneficial for the uniform current distribution.

In the row direction of the sub-pixels 12, each of the distances between the sides of the contact region A and the connecting surface 1210 of the corresponding anode 121 that are close to each other in a single one of the sub-pixels 12 is defined as a first distance d1. It is defined that in the column direction of the sub-pixels 12, each of the distances between the sides of the contact region A and the connecting surface 1210 of the corresponding anode 121 that are close to each other in a single one of the sub-pixels 12 is a second distance d2.

In a single one of the sub-pixels 12, the first distance d1 and the second distance d2 may be equal or unequal, which may be configured according to actual needs.

It should be understood that, compared with the embodiment in which the first distance d1 and the second distance d2 in a single one of the sub-pixels 12 are not equal, the embodiment in which the first distance d1 and the second distance d2 in a single one of the sub-pixels 12 are equal may be more conducive to the uniform distribution of current.

In some embodiments, a length of the short side of the rectangle formed by the contact region A may be less than half of the width of the corresponding one of the sub-pixels 12. Thus, without affecting the pixel aperture of the sub-pixels 12, the yield of the vias of the anode conductive vias 111 and the conductivity between the anode 121 of each of the sub-pixels 12 and the corresponding one of the anode conductive vias 111 may be ensured, so as to avoid the distances between the sides where the contact region A and the connecting surface 1210 of the corresponding anode 121 are close to each other from being too small, which may affect the distribution uniformity of the current. A width direction of the sub-pixels 12 is the row direction of the sub-pixels 12.

In this embodiment, the width W3 of the contact region A of each of the blue pixels B may be less than half of the width of the corresponding one of the sub-pixels 12, and the contact region A may be located at the geometric center of the corresponding connecting surface 1210.

The light-emitting carrier plate 10 may further include an encapsulation layer 13. The encapsulation layer 13 may be located on the side of the sub-pixels 12 away from the glass substrate 11. There are no restrictions on the material of the encapsulation layer 13, which can be selected according to actual requirements.

The light-emitting carrier plate 10 may further include a plurality of isolation structures 14. Each of the isolation structures 14 may be disposed on a side of a corresponding one of the sub-pixels 12 and be used to isolate the light-emitting layers 122 of the sub-pixels 12 to avoid the problem of pixel crosstalk. The isolation structures 14 may isolate the cathode 123 of the sub-pixels 12 or electrically connect the cathodes 123 of adjacent sub-pixels 12. The material of the isolation structures 14 is not limited here and can be selected according to actual requirements.

In this embodiment, the isolation structure 14 may further isolate the cathode 123 of the sub-pixels 12. The cathode 123 of the sub-pixels 12 may form an integral layer structure. The cathode 123 may be located on the side of the isolation structures 14 away from the glass substrate 11. The isolation structures 14 are insulative.

The specific structure of the isolation structures 14 is not limited here, and it can be selected according to actual requirements.

The driving circuit layer 22 may further include a plurality of anode electrodes 221 and a plurality of cathode electrodes 222. A side of the glass substrate 11 close to the silicon-based drive substrate 20 may further include a plurality of anode extension electrodes 15 and a plurality of cathode extension electrodes 16. Each of the anode electrodes 221 may be arranged in one-to-one correspondence with a corresponding one of the anode extension electrodes 15 and be electrically connected with the corresponding one of the anode extension electrodes 15. Each of the cathode electrodes 222 may be set in one-to-one correspondence with a corresponding one of the cathode extension electrodes 16 and be electrically connected with the corresponding one of the cathode extension electrodes 16. Each of the anode conductive vias 111 may be arranged in one-to-one correspondence with a corresponding one of the anode extension electrodes 15 and be electrically connected with the corresponding one of the anode extension electrodes 15. Each of the cathode conductive holes 112 may be arranged in one-to-one correspondence with a corresponding one of the cathode extension electrodes 16 and be electrically connected with the corresponding one of the cathode extension electrodes 16.

In other embodiments, the anode conductive vias 111 may be electrically connected to the driving circuit layer 22 through other ways, and the cathode conductive holes 112 may be electrically connected to the driving circuit layer 22 through other ways.

Please refer to FIG. 5, FIG. 5 is a structural schematic view of a display device provided by an embodiment of the present disclosure.

The present disclosure provides a display device 300. The display device 300 includes a mainboard 200 and the above-mentioned display panel 100. The display device 300 in the embodiment of the present disclosure is an active matrix organic light-emitting diodes (AMOLED).

The mainboard 200 is electrically connected to the display panel 100. The mainboard 200 may be configured to transmit various signals to the display panel 100 to control the display panel 100 to display pictures. For example, a clock signal (CK), a low potential signal (Vss), a power supply voltage signal (VDD), and a data signal (Data) required by the driving circuit layer, etc.

In the above embodiments, the descriptions of each embodiment have their own emphases. For the parts not elaborated in a certain embodiment, the relevant descriptions of other embodiments may be referred to.

The above are only the embodiments of the present disclosure, which do not limit the protection scope of the present disclosure. Any equivalent structure or equivalent process transformation made using the content of the specification and drawings of the present disclosure, directly or indirectly applied in other related technical fields, is similarly included within the protection scope of the present disclosure.

1. A display panel, comprising:
a silicon-based driving substrate; and
a light-emitting carrier plate, bonded to the silicon-based driving substrate;
wherein the light-emitting carrier plate comprises:
a glass substrate, comprising a plurality of anode conductive vias; and
a plurality of sub-pixels of different colors, disposed on a surface of a side of the glass substrate; wherein each of the sub-pixels comprises an anode, and the anode of each of the sub-pixels is arranged in one-to-one correspondence with one of the plurality of anode conductive vias; a surface of a side of the anode of each of the sub-pixels close to the glass substrate is defined as a connecting surface; the connecting surface covers and contacts a corresponding one of the anode conductive vias, and a contact region is formed on the connecting surface; the sub-pixels of different colors have different service lives; and
the sub-pixel having shorter service life has a larger contact region on the anode.

2. The display panel according to claim 1, wherein the contact region of each of the sub-pixels is located at a geometric center of a corresponding connecting surface.

3. The display panel according to claim 1, wherein in a direction parallel to the glass substrate, a shape of the contact region is the same as or similar to that of a corresponding one of the sub-pixels.

4. The display panel according to claim 3, wherein in the direction parallel to the glass substrate, the shapes of the sub-pixels and the contact regions are all rectangular; the sub-pixels are arranged in an array; in each row of the sub-pixels, the sub-pixels of different colors are arranged side by side periodically and are aligned; in each row of the sub-pixels, the contact regions of the sub-pixels of different colors respectively form a plurality of rectangles with equal lengths and unequal widths, and short sides of the rectangles of the contact regions are aligned; and the short sides of the rectangles of contact regions are parallel to a row direction of the sub-pixels.

5. The display panel according to claim 4, wherein in each of the sub-pixels, the short side of the rectangle formed by the contact region is parallel to the short side of the rectangle formed by the corresponding one of the sub-pixels.

6. The display panel according to claim 5, wherein a length of the short side of the rectangle formed by each of the contact regions is less than half of a width of the corresponding one of the sub-pixels.

7. The display panel according to claim 1, wherein the plurality of sub-pixels of different colors are respectively defined as red pixels, green pixels, and blue pixels; the service life of the red pixels are greater than that of the green pixels, and the service life of the green pixels are greater than that of the blue pixels; an area of the contact region of each of the red pixels is smaller than that of the contact region of each of the green pixels; the area of the contact region of each of the green pixels is smaller than that of the contact region of each of the blue pixels.

8. The display panel according to claim 7, wherein a ratio of a light-emitting area of each of the red pixels, a light-emitting area of each of the green pixels, and a light-emitting area of each of the blue pixels is 2:1:2.

9. The display panel according to claim 1, wherein an area of each of the contact regions accounts for 1/4 to 1/2 of an area of a corresponding connecting surface.

10. The display panel according to claim 1, wherein the silicon-based driving substrate comprises a silicon substrate and a driving circuit layer; the driving circuit layer is arranged at a side of the silicon substrate close to the light-emitting carrier plate.

11. The display panel according to claim 10, wherein the driving circuit layer comprises an active driving circuit integrated on the silicon substrate.

12. A display device, comprising a mainboard and a display panel, wherein the display panel comprises:
a silicon-based driving substrate;
a light-emitting carrier plate, bonded to the silicon-based driving substrate;
wherein the light-emitting carrier plate comprises:
a glass substrate, comprising a plurality of anode conductive vias;
a plurality of sub-pixels of different colors, disposed on a surface of a side of the glass substrate; wherein each of the sub-pixels comprises an anode, and the anode of each of the sub-pixels is arranged in one-to-one correspondence with one of the plurality of anode conductive vias; a surface of a side of the anode of each of the sub-pixels close to the glass substrate is defined as a connecting surface; the connecting surface covers and contacts a corresponding one of the anode conductive vias, and a contact region is formed on the connecting surface; the sub-pixels of different colors have different service lives; and
the sub-pixel having shorter service life has a larger contact region on the anode.

13.The display device according to claim 12, wherein the contact region of each of the sub-pixels is located at a geometric center of a corresponding connecting surface.

14. The display device according to claim 12, wherein in a direction parallel to the glass substrate, a shape of the contact region is the same as or similar to that of a corresponding one of the sub-pixels.

15. The display device according to claim 14, wherein in the direction parallel to the glass substrate, the shapes of the sub-pixels and the contact regions are all rectangular; the sub-pixels are arranged in an array; in each row of the sub-pixels, the sub-pixels of different colors are arranged side by side periodically and are aligned; in each row of the sub-pixels, the contact regions of the sub-pixels of different colors respectively form a plurality of rectangles with equal lengths and unequal widths, and the short sides of the rectangles of the contact regions are aligned; and the short sides of the rectangles of contact regions are parallel to a row direction of the sub-pixels.

16. The display device according to claim 15, wherein in each of the sub-pixels, the short side of the rectangle formed by the contact region is parallel to the short side of the rectangle formed by the corresponding one of the sub-pixels.

17. The display device according to claim 16, wherein a length of the short side of the rectangle formed by each of the contact regions is less than half of the width of the corresponding one of the sub-pixels.

18. The display device according to claim 12, wherein the plurality of sub-pixels of different colors are respectively defined as red pixels, green pixels, and blue pixels; the service life of the red pixels are greater than that of the green pixels, and the service life of the green pixels are greater than that of the blue pixels; an area of the contact region of each of the red pixels is smaller than that of the contact region of each of the green pixels; the area of the contact region of each of the green pixels is smaller than that of the contact region of each of the blue pixels.

19. The display device according to claim 18, wherein a ratio of a light-emitting area of each of the red pixels, a light-emitting area of each of the green pixels, and a light-emitting area of each of the blue pixels is 2:1:2.

20. The display device according to claim 12, wherein an area of each of the contact regions accounts for 1/4 to 1/2 of an area of a corresponding connecting surface.
